(19) United States
(12) Patent Application Publication
(10) Pub. No.: US 2011/0215431 A1
(43) Pub. Date: Sep. 8, 2011

(54) ELECTRICAL CONTACT CONFIGURATION OF MICRO-ELECTROMECHANICAL COMPONENT AND FABRICATION METHOD

(75) Inventors: Philippe Azoley, Grenoble (FR); Jean-Michel Gilet, Fontaine (FR); Stéphane Nicolas, Meylan (FR)

(73) Assignee: TRONIC'S MICROSYSTEMS

(21) Appl. No.: 13/129,211

(22) PCT Filed: Nov. 10, 2009
(86) PCT No.: PCT/IB09/54988

§ 371 Date: May 13, 2011

(30) Foreign Application Priority Data
Nov. 25, 2008 (FR) 0857989

(51) Int. Cl. H01L 29/84; H01L 21/02

(52) U.S. Cl. 257/417; 438/50; 257/E29.324; 257/E21.002

(57) ABSTRACT

A micro-electromechanical component produced from a semiconductor substrate, comprising an internal moving portion which includes conductive elements and contacts on its outer surface, said contacts being electrically connected to said conductive elements, said electrical contacts being capable of accommodating soldered interconnect wires which are themselves designed to be connected to electrical contacts provided on device which accommodates said component, characterized in that electrical contacts are arranged in an area which extends between upper face of the component and lateral face, said contacts having a concave shape and having two regions capable of accommodating soldered interconnect wires, said regions being substantially perpendicular to each other and parallel to said upper face and said lateral face respectively.

### CROSS REFERENCE TO RELATED APPLICATIONS

This application is a National Stage application under 35 U.S.C. §371 of PCT Application No. PCT/IB2009/054988, filed Nov. 10, 2009, which claims priority to French Application No. FR 0857989, filed Nov. 25, 2008, entitled “Electrical Contact Configuration of Microelectromechanical Component and Fabrication Metho,” which claims the benefit under 35 U.S.C. §119 (e) to U.S. Application No. 61/117,803, filed Nov. 25, 2008.

### FIELD OF THE INVENTION

The invention relates to the field of microelectronics, more especially to micro-electromechanical systems (MEMS) technology. More specifically, it aims to provide an improvement in the ways in which MEMS components are electrically connected to other electronic components.

More particularly, it relates to an electrical contact configuration which facilitates various mounting layouts for MEMS components.

### DESCRIPTION OF THE PRIOR ART

Generally speaking, MEMS components are frequently used as sensors and make it possible to convert physical quantities such as pressure, acceleration and force into electrical signals. An MEMS component therefore contains a moving internal portion which is connected to conductive elements which make it possible to transfer the signal thus generated to electrical contacts which can be accessed outside the component.

An MEMS component is generally mounted on or alongside an electronic component which is used to ensure processing of the signal generated by the MEMS component in order to output a correctly formatted signal. In practice, connection between the output terminals of the MEMS component and the input terminals of the processing component can be realized in various ways.

A first technique involves using bump contacts located between these various terminals; this requires geometrical alignment of the contacts of the MEMS component with those of the processing component. An alternative to this technique, referred to as “bumping”, involves using interconnect wires which are soldered, firstly, to the electrical contacts on the surface of the MEMS component and, secondly, to the input terminals of the processing component.

This technique is referred to as wire bonding and allows greater flexibility when positioning the various terminals. However, two soldered joints have to be made on the bond wire for every connection, namely, firstly one on the electrical contacts of the

MEMS component and, secondly, one on the electrical contacts of the signal processing component.

These soldering operations are performed using appropriate apparatus which comprises a wire bonding head which moves at right angles to the surface of the contact in order to solder the bond wire onto it.

In the case of MEMS components designed to measure physical quantities in a given direction, the layout and orientation of the MEMS component must be chosen taking into account the conditions under which the device which contains the sensor is used.

For instance, a mono-axial accelerometer measures direction along a predetermined axis as a function of the displacement of the moving portion due to the effect of a force which corresponds to the acceleration to be measured.

Thus, depending on the displacement mode of the moving portion of the MEMS component and using mono-axial sensors, the number of detectors used must be the same as the number of acceleration components that are to be measured.

This means that two acceleration components in the main plane of the device are detected by using two mono-axial MEMS sensors which have their detection axes arranged at right angles in the plane in question. Measuring acceleration along the third axis, i.e. in a direction perpendicular to the main plane of the device, involves either using an MEMS sensor of a different kind or fitting the same type of MEMS sensor, pivoted through 90°.

Nevertheless, it should be noted that, if connection is obtained by using a wire bonding technique, the MEMS sensor used cannot be strictly identical given the fact that the electrical contacts, having been pivoted, have a configuration which makes them inaccessible to soldering systems.

Another problem encountered with MEMS sensors is their overall dimensions which can be relatively large. In fact, the sensors generally have dimensions in the plane of the substrate which are much larger than their height, measured at right angles to the substrate plane. It is therefore obvious that the detectors occupy a relatively large surface area compared with their height. Document WO 2006/134233 describes a solution to this problem of overall size by proposing that MEMS sensors be mounted on their edges. This solution involves realizing multi-axial MEMS sensors which have a series of contacts made on the edge of the component, i.e. the lateral face which is revealed after separating the various components produced on a single substrate or wafer. The surface area taken up by the sensor on the substrate which accommodates it is therefore reduced.

However, the drawback of this technique is that it involves operations to obtain metallization on the individualized components after they have been separated from the common wafer. It is readily apparent that these various manipulation and metallization operations are complex to implement and increase the cost of such components considerably. Moreover, as stated above, such a sensor can only be mounted on its edge and cannot have any other orientation because its contacts are only accessible for making bond-wire interconnections when the sensor is mounted edgewise.—A—The problem which the invention therefore aims to solve is that of producing

MEMS components which have the following features: they can be used in various orientations and, especially after pivoting through 90°, they are compatible with conventional wire bonding techniques and can be produced collectively, i.e. several MEMS components can be produced on a single wafer before being separated.

### SUMMARY OF THE INVENTION

The invention therefore relates to a micro-electromechanical component produced from a single wafer of a semiconductor material. This component comprises, conventionally, an internal moving portion which includes conductive elements and contacts on its outer surface. These contacts are electrically connected to conductive elements and are capable of accommodating soldered interconnect wires which are themselves designed to be connected to electrical contacts provided on a device which accommodates the component.

In accordance with the invention, this component is characterized in that the electrical contacts are arranged in an area which extends between the upper face of the component and a lateral face. These contacts have a concave shape and have two regions which are substantially perpendicular to each other and parallel to the upper face and the lateral face of the component respectively, and in that both regions are capable of accommodating soldered interconnect wires.

In other words, the invention involves producing contacts which have a complex shape and a geometry such that they have a surface which is parallel to that of the component intended to accommodate the MEMS component, regardless whether the latter is arranged conventionally (flat) or pivoted through 90°. In other words, the electrical contacts of the MEMS component always have a portion which is parallel to the contacts of the processing component so that bond-wire soldering operations can be performed using conventional equipment. In practice, the lateral face which is opposite that which comprises the electrical contacts is advantageously flat so that it can be positioned stably on the device, thereby accentuating the distinctive component.

In practice, the MEMS component can be produced by assembling various layers made up of separate wafers. In this case, the internal moving portion is produced on a first layer and can be covered by a second layer which forms a cap, in which case the electrical contacts may advantageously be located on the cap in question so that they are accessible on the upper face of the component.

In this case, the distinctive electrical contacts are produced on a first wafer which is different to that from which the moving portions which form the core of the sensor are made.

In practice, the two perpendicular regions of the electrical contact can be linked to each other by a flat zone which slopes relative to the upper face of the component at an angle which is neither zero nor straight.

Advantageously, the two perpendicular regions of the electrical contact have surfaces of the same order of magnitude, i.e. surface areas having a ratio which is preferably less than 5. This makes it possible to reap the benefits of a surface area which is sufficiently large to ensure soldering using conventional means while ensuring that the electrical contact does not occupy an excessively large surface area on the component.

Thus, the invention also relates to a method for fabricating such a component from a wafer of a semiconductor material. In this case, the method according to the invention is characterized in that it involves the following steps:

On each future component which is present on the wafer, forming at least one recess at the level of a straight edge which links the upper face and the lateral face of the future component, this recess comprising a first region which is substantially parallel to the lateral surface and a second region which is substantially parallel to the upper surface;

Then, depositing a metal layer which continuously covers both these regions, this metal layer being electrically connected to the conductive elements inside the component;

Finally, separating the various components formed on the same wafer in order to individualize them without the need for subsequent operations to create electrical contacts.

In practice, this recess can advantageously be produced by a succession of the following steps: a wet etching process intended to form the junction surface between the first and second regions of the contacts designed to accommodate the interconnect wires, then a dry etching process intended to form the second region which is parallel to the lateral face of the component.

### BRIEF DESCRIPTION OF THE DRAWINGS

The way in which the invention is implemented and its resulting advantages will be more readily understood from the following description of its embodiments, reference being made to the accompanying drawings in which: FIGS. 1 to 7 are cross-sectional views of an MEMS component during the course of fabrication as the various steps in the method are completed.

FIGS. 8 and 9 are cross-sectional views of the component produced in the previous Figures mounted on an additional component in two different orientations.

FIGS. 10 and 11 are cross-sectional views of the component produced in the previous Figures connected to an additional component and mounted on a support substrate in two different orientations.

### DESCRIPTION OF THE PREFERRED EMBODIMENT

FIGS. 1 to 7 illustrate a specific method for implementing the invention but only show the main steps that relate to the invention. Necessary but conventional steps which have no direct bearing on the invention are not described in detail. Similarly, the dimensions shown, especially thicknesses, are given for information only and may differ from the real dimensions insofar as they were chosen in order to make the invention more readily comprehensible.

FIG. 1 shows a silicon wafer 1 intended to form the cap of a future MEMS component. For this purpose, the wafer comprises, on its upper face, oxidation layer 2 and marks 3 and 4 which are conventionally arranged to allow alignment and ultimate dicing of the wafer in order to separate the various components produced thereon. This lid 1 comprises, on its lower face, passivation layer 5 and recess 6 which is made after opening passivation layer 5 and an etching process used to define the cavity which is located vertically above the future moving areas of the MEMS component.

In a second step shown in FIG. 2, a partial recess 10 is formed on upper face 12. The term “upper face” is taken to mean a face which is parallel to the main plane of wafer 1 and will be located on the outside of the future component.

This recess 10 is produced conventionally by wet etching which makes it possible to define sloping flank 14 and a flat 15 which forms the bottom of recess 10 and is parallel to upper face 12. This flat 15 extends internally into the volume of the future component and future lateral face 13 which is shown in a dashed line vertically below dicing mark 3 shown in FIG. 1.

A metal layer intended to form tracks 20 and 21 is deposited in a subsequent step which is shown in FIG. 3. These tracks 20, 21 are deposited on passivation layer 5 on the lower face of the wafer.

Layer 20 is deposited vertically below flank 14 of recess 10. Lower face 7 is then covered in a layer of a dielectric material which is intended to insulate electrode 20. This dielectric layer 24 which covers the entire lower face of the wafer is then etched in order to produce opening 27 which provides access to electrode 20. A step to deposit sealing metal 30 is then performed; this seal makes it possible to perform assembly with the wafer in which the moving parts of the MEMS component will have been produced. The layers which form the sealing material are then arranged so as to form a barrier around recess 6. Portion 30 is located vertically below the lateral face of the component. Deposited metal 32 is electrically connected to electrode 20 via a portion which extends into opening 27.

Then, in a subsequent step shown in FIG. 4, lid 35 which is thus produced is assembled with a second wafer 40 on which moving portions 41, which are located vertically below recess 6, have been produced. Wafer 40 includes intermediate insulating layer 42 which makes it possible to define various electrical connections, especially conductive portions 44 which will make it possible to pick off the electrical signal generated at the level of moving parts 41. Thus, conductive portion 44 is in contact with electrode 20 via bump contact 32.

After assembling the two wafers as shown in FIG. 5, a step is then performed to enlarge recess 10. This enlargement is achieved by dry etching which makes it possible to eliminate the portion of the substrate which is vertically above the contact of electrode 20 so as to expose the latter.

Lateral flank 14 is thus extended downwards towards sloping flank 54. Dry etching is used to produce flank 55 which is perpendicular to upper face 12 of the component.

This flank 55 is intended to accommodate an area of the future distinctive contact and must therefore be sufficiently high to allow soldering of the bond wires. Nevertheless, it must not be excessively high because, as explained below, it will have to receive metal deposited on a surface which is therefore perpendicular to the upper face of the wafer. In a subsequent step shown in FIG. 6, a layer of a dielectric material is deposited over the entire upper face of the component. This layer 56 is etched in the area of opening 57 so as to obtain access to electrode 20.

Then, in a subsequent step shown in FIG. 7, a metal layer is deposited on recess 10 so as to cover the vertical flank 55, sloping flank 54 and bottom 58 of the recess. This creates the distinctive contact 60 which has a first region 62 which is parallel to upper face 12 of the wafer and second region 61 which is parallel to the future lateral face of the component. These two regions are linked by portion 63 which covers sloping flank 54.

This metallization step can be performed in various ways, ensuring that the deposited metal is as compliant as possible, especially in the vicinity of vertical flank 55.

The metal can be deposited using a Physical Vapor Deposition (PVD) technique which may or may not be combined with using a fixture to orient the wafer, making it possible to deposit metal on vertical flank 55.

It is thus possible to deposit metal over the entire exposed surface area of the component on which a mask will previously have been produced by depositing and structuring a film which has openings in those areas where the deposited metal is to be preserved. It is also possible to deposit the metal through a shadow mask with, however, the risk of greater variation in the thickness of the deposited metal.

In a subsequent step which is not shown, the various components are separated from each other by cutting the wafer in accordance with initial marks 3, 4.

It goes without saying that the method described above is merely illustrative and that other methods involving classic elementary steps can be implemented in order to achieve a structure which is similar and embodies the essential aspects of the invention.

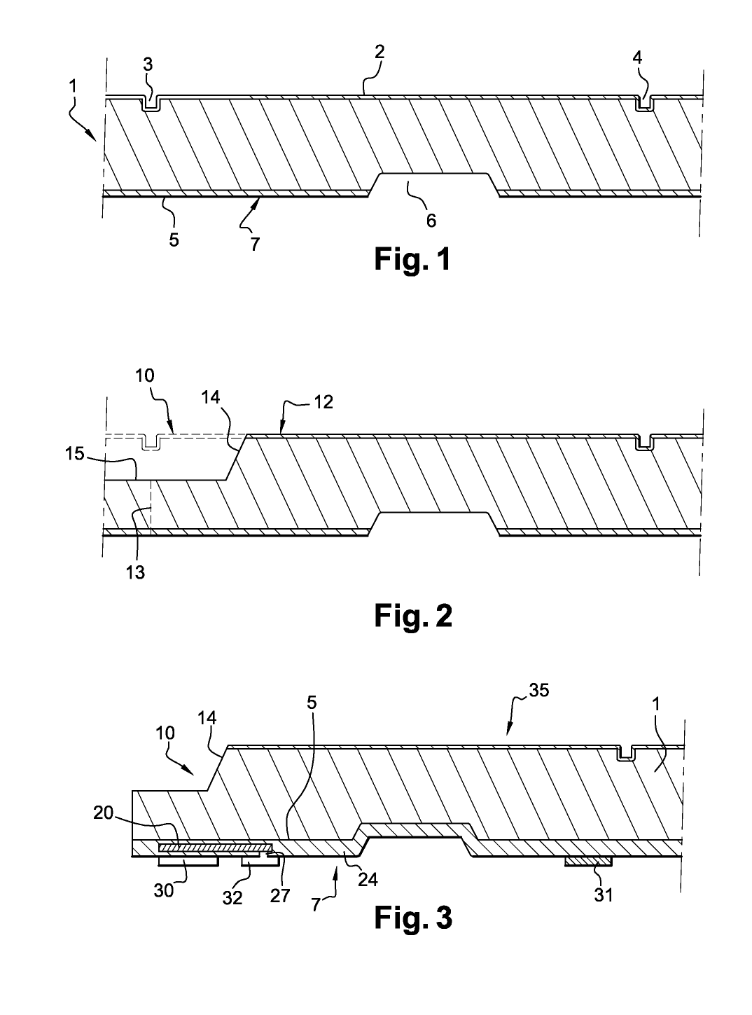

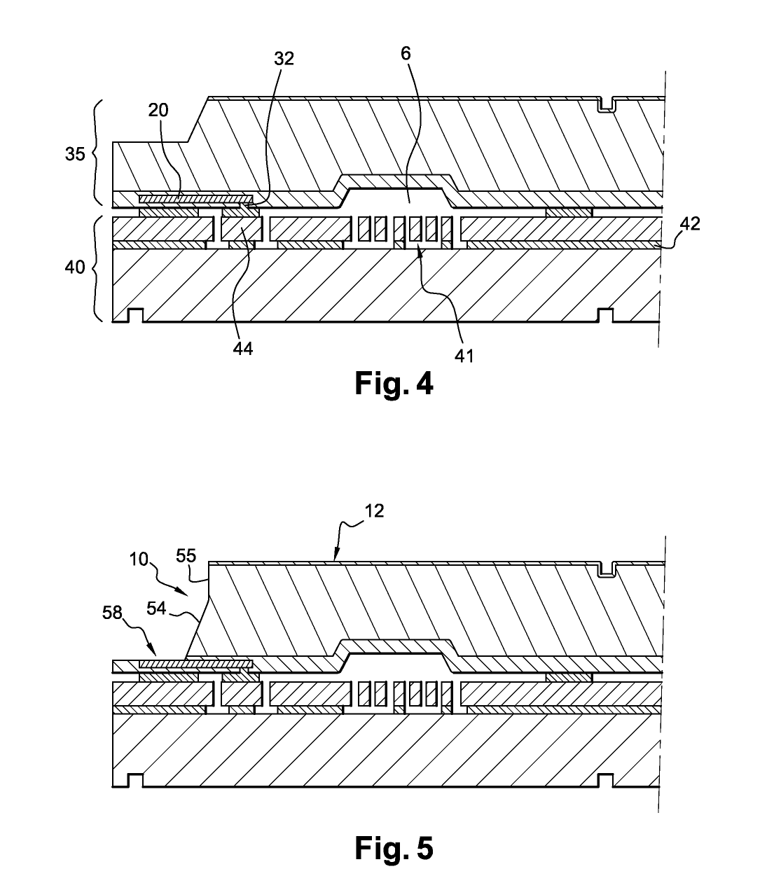

After finalizing the component, it can be used in the two types of setup shown in FIGS. 8 and 9. Thus, as shown in FIG. 8, MEMS component 70 can be placed on another component, especially a processing component 80 in which the signal, resulting from the mechanical phenomena which occur inside MEMS component 70, is shaped and formatted. In this case, MEMS component 70 rests substantially flat on its inner face 86 on component 80, component 80 has contacts 81 which allow connection to MEMS component 70 at the level of contact 60 and, more precisely, portion 61 which is parallel to upper face 12 of component 70.

Conversely and as shown in FIG. 9, the same component 70 can be mounted after pivoting it through 90° so that its upper face 12 is perpendicular to the upper face 83 of component 81. MEMS component 70 then rests on its lateral face 87 on component 80. Interconnect wire 84 is connected firstly to contact 81 of component 80 and secondly to portion 62 of distinctive contact 60.

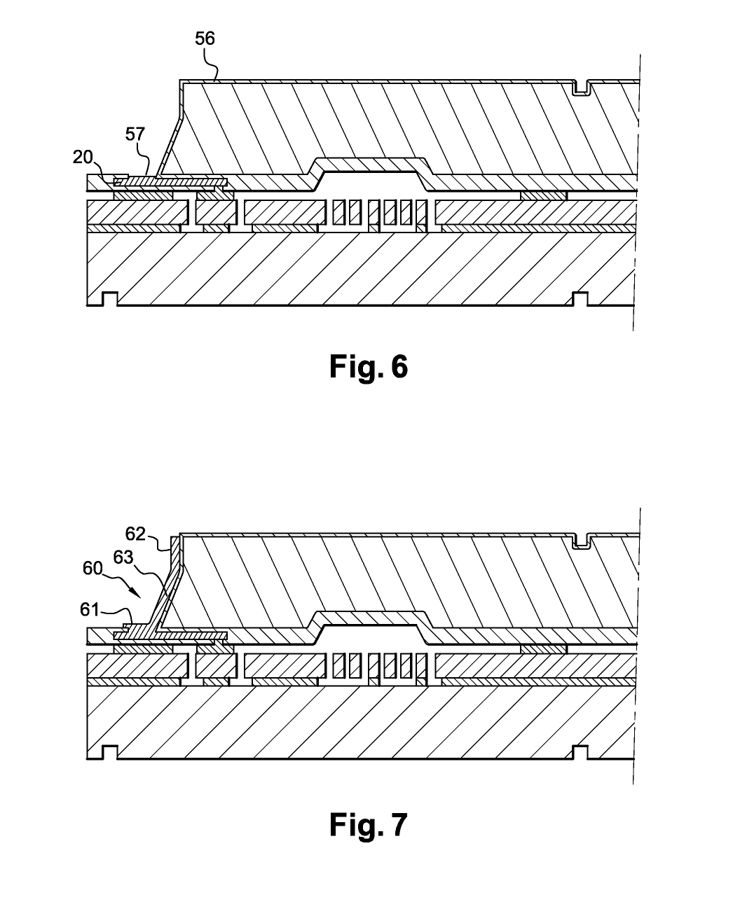

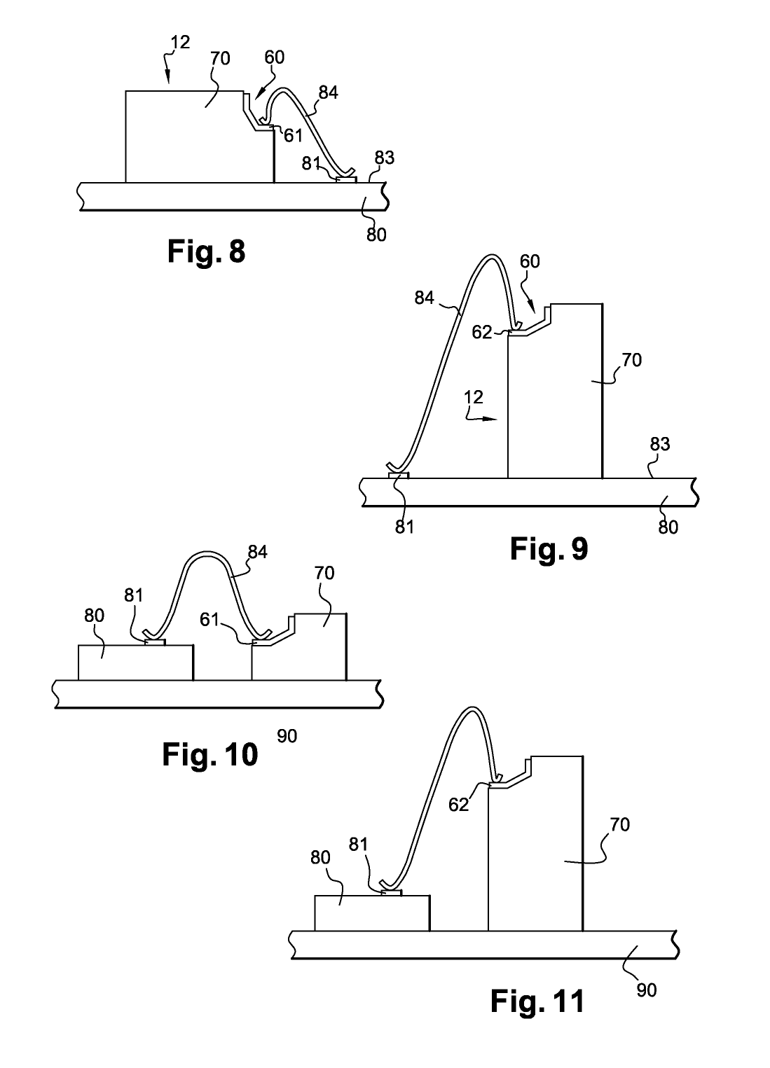

Similarly, as shown in FIG. 10, MEMS component 70 can be mounted on its lower face on support substrate 90 in the vicinity of processing component 80. It is electrically connected to it by interconnect wire 84 which is soldered firstly to contact 81 of component 80 and secondly to contact 60 and, more precisely, to portion 61 which is parallel to the upper face of MEMS component 70. Conversely and as shown in FIG. 11, the same MEMS component 70 can be mounted on support substrate 90 on its lateral face or side edge. In this case, electrical connection with the processing component is obtained via portion 62 of contact 60 which is parallel to the lateral face.

The above description makes it apparent that the invention has the major advantage of allowing vertical and/or horizontal mounting of an identical MEMS component in a manner which is compatible with wire bonding techniques. Thus, a single identical component produced using a single fabrication chain can be used in two different mounting orientations.

Industrial applications One preferred application of the invention is to produce sensors designed to measure vector quantities, especially inertia quantities. This includes linear or angular acceleration sensors such as accelerometers and rate gyros. The invention is also suitable for producing sensors where orientation or positioning in the sensitive area is a requirement. Examples include pressure sensors which incorporate a deformable membrane; their positioning, especially their communication with the space in which the pressure is to be measured, can thus be optimized.

1. Micro-electromechanical component produced from a semiconductor substrate, comprising an internal moving portion which includes conductive elements and contacts on its outer surface, said contacts being electrically connected to said conductive elements, said electrical contacts being capable of accommodating soldered interconnect wires which are themselves designed to be connected to electrical contacts provided on device which accommodates said component, characterized in that electrical contacts are arranged in an area which extends between upper face of the component and lateral face, said contacts having a concave shape and having two regions capable of accommodating soldered interconnect wires, said regions being substantially perpendicular to each other and parallel to said upper face and said lateral face respectively.

2. Component as claimed in claim 1, characterized in that the two perpendicular regions of the electrical contact are linked by a flat zone which slopes relative to upper face.

3. Component as claimed in claim 1, characterized in that it comprises a portion forming a cap which covers the internal moving portion, electrical contacts being located on said cap.

4. Component as claimed in claim 1, characterized in that the two regions have surface areas having a ratio of less than 5.

5. Component as claimed in claim 1, characterized in that lateral face opposite face which accommodates electrical contacts is substantially flat.

6. Method of fabricating micro-electromechanical components from a wafer of a semiconductor material, each component comprising an internal moving portion which includes conductive elements, and contacts on its outer face, said contacts being electrically connected to said conductive elements, the contacts being designed to accommodate soldered conducting wires allowing connection to electrical contacts of other components, characterized in that it comprises the following steps:
on each future component on said wafer, forming at least one recess at the level of a straight edge linking upper face and lateral face of the future component, said recess comprising a first region which is substantially parallel to lateral surface and a second region which is substantially parallel to upper surface;
depositing a metal layer which continuously covers both regions of each recess, said recess being electrically connected to the conductive elements;
separating the various components formed on the same wafer.

7. Method as claimed in claim 6, characterized in that said recess is produced by succession of the following steps: a wet etching process intended to form, on junction surface between the first region and the second region and a dry etching process intended to form the second region which is parallel to lateral face.
